(19) United States
(12) Patent Application Publication
(10) Pub. No.: US 2025/0230568 A1
(43) Pub. Date: Jul. 17, 2025

(54) HEATSINK AND ASSOCIATED METHOD OF MAKING THE SAME

(71) Applicant: FABRIC8LABS, INC., San Diego, CA (US)

(72) Inventors: Ian Winfield, Oceanside, CA (US); Charles Biset, San Diego, CA (US); Tim Ouradnik, San Diego, CA (US); Joseph Workman, San Diego, CA (US)

(21) Appl. No.: 18/911,997

(22) Filed: Oct. 10, 2024

Related U.S. Application Data
(60) Provisional application No. 63/620,204, filed on Jan. 12, 2024.

(51) Int. Cl. C25D 7/00; H05K 7/20

(52) U.S. Cl. CPC C25D 7/00; H05K 7/2039

(57) ABSTRACT

A method of making a heatsink includes positioning a cathode, which includes a build plate and a metallic foil supported on the build plate, into an electrolyte solution. The method also includes positioning a deposition anode array into the electrolyte solution, connecting the metallic foil to a power source, and connecting one or more deposition anodes of the deposition anode array to the power source. The method further includes transmitting electrical energy from the power source through the one or more deposition anodes, through the electrolyte solution, and to the metallic foil, such that material is deposited onto the metallic foil and forms at least a portion of a heat exchange feature of a heatsink. The heatsink includes the metallic foil and the material deposited onto the metallic foil.

### CROSS-REFERENCE TO RELATED APPLICATION

This application claims the benefit of U.S. Provisional Patent Application No. 63/620,204, filed Jan. 12, 2024, which is incorporated herein by reference in its entirety.

### FIELD

This disclosure relates generally to electrochemical deposition methods and systems, and the associated parts made thereby, and more particularly to methods of making a cathode for an electrochemical deposition system and associated heatsinks made by the electrochemical deposition system.

### BACKGROUND

Electrochemical deposition manufacturing utilizes electrochemical reactions to manufacture parts in an additive manufacturing manner. In an electrochemical deposition manufacturing process, a metal part is constructed by plating charged metal ions onto a surface of a cathode in an electrolyte solution. This technique relies on placing a deposition anode physically close to the cathode in the presence of a deposition solution (the electrolyte), and energizing the anode causing charge to flow through the anode. This creates an electrochemical reduction reaction to occur at the cathode near the anode and deposition of material on the cathode.

Although electrochemical deposition manufacturing techniques provide distinct advantages over other types of additive manufacturing processes, such as selective laser melting and electron beam melting, making cathodes for conventional electrochemical deposition systems can be difficult. Moreover, conventional cathodes are not integrated into the parts manufactured by electrochemical deposition manufacturing techniques.

Additionally, although conventional electrochemical deposition manufacturing processes can make parts that other types of manufacturing processes are incapable of making, such conventional electrochemical deposition manufacturing processes are not fully utilized to make certain types of parts with difficult to manufacture features.

### SUMMARY

The subject matter of the present application has been developed in response to the present state of the art, and in particular, in response to the shortcomings of conventional electrochemical deposition manufacturing processes, which have not yet been fully solved by currently available techniques. Accordingly, the subject matter of the present application has been developed to provide a cathode of an electrochemical deposition system, a method of making a cathode of an electrochemical deposition system, a heatsink made by an electrochemical deposition system, and a method of making a heatsink, which overcome at least some of the shortcomings of prior art techniques.

The following is a non-exhaustive list of examples, which may or may not be claimed, of the subject matter, disclosed herein.

Disclosed herein is a method of making a heatsink. The method includes positioning a cathode, including a build plate and a metallic foil supported on the build plate, into an electrolyte solution such that the metallic foil of the cathode directly contacts the electrolyte solution. The method also includes positioning a deposition anode array, including a plurality of deposition anodes, into the electrolyte solution such that a gap is established between the metallic foil and the plurality of deposition anodes. The method further includes connecting the metallic foil to a power source. The method additionally includes connecting one or more deposition anodes of the plurality of deposition anodes to the power source. The method also includes transmitting electrical energy from the power source through the one or more deposition anodes of the plurality of deposition anodes, through the electrolyte solution, and to the metallic foil, such that material is deposited onto the metallic foil and forms at least a portion of a heat exchange feature of the heatsink. The method further includes removing the metallic foil, and the material deposited onto the metallic foil, from the build plate. The heatsink includes the metallic foil and the material deposited onto the metallic foil. The preceding subject matter of this paragraph characterizes example 1 of the present disclosure.

The build plate includes a raised platform. The cathode further includes a retaining device engaged with the metallic foil to retain the metallic foil against the build plate and to seal the build plate around a support surface of the raised platform. A deposition surface of the metallic foil is proud of the retaining device. The material is deposited onto the deposition surface of the metallic foil. The preceding subject matter of this paragraph characterizes example 2 of the present disclosure, wherein example 2 also includes the subject matter according to example 1, above.

The method further includes urging the metallic foil against the build plate via negative pressure. The preceding subject matter of this paragraph characterizes example 3 of the present disclosure, wherein example 3 also includes the subject matter according to any of examples 1-2, above.

The method further includes sensing a pressure between the metallic foil and the build plate. The preceding subject matter of this paragraph characterizes example 4 of the present disclosure, wherein example 4 also includes the subject matter according to example 3, above.

The method further includes adjusting the negative pressure in response to a sensed pressure between the metallic foil and the build plate being outside of a desired negative pressure range. The preceding subject matter of this paragraph characterizes example 5 of the present disclosure, wherein example 5 also includes the subject matter according to example 4, above.

Removing the metallic foil, and the material deposited onto the metallic foil, from the build plate includes removing the negative pressure between the metallic foil and the build plate. The preceding subject matter of this paragraph characterizes example 6 of the present disclosure, wherein example 6 also includes the subject matter according to any of examples 3-5, above.

The method further includes trimming a peripheral portion from the metallic foil after the metallic foil, and the material deposited onto the metallic foil, are removed from the build plate. The preceding subject matter of this paragraph characterizes example 7 of the present disclosure, wherein example 7 also includes the subject matter according to any of examples 1-6, above.

The method further includes reshaping the metallic foil after the metallic foil, and the material deposited onto the metallic foil, are removed from the build plate. The preceding subject matter of this paragraph characterizes example 8 of the present disclosure, wherein example 8 also includes the subject matter according to any of examples 1-7, above.

Reshaping the metallic foil includes bending the metallic foil from a planar shape to a non-planar shape. The preceding subject matter of this paragraph characterizes example 9 of the present disclosure, wherein example 9 also includes the subject matter according to example 8, above.

The material is deposited onto a deposition surface of the metallic foil. When the metallic foil has the non-planar shape, the deposition surface of the metallic foil has a convex shape. The preceding subject matter of this paragraph characterizes example 10 of the present disclosure, wherein example 10 also includes the subject matter according to example 9, above.

The material is deposited onto a deposition surface of the metallic foil. When the metallic foil has the non-planar shape, the deposition surface of the metallic foil has a concave shape. The preceding subject matter of this paragraph characterizes example 11 of the present disclosure, wherein example 11 also includes the subject matter according to example 9, above.

The material is deposited onto a deposition surface of the metallic foil. When the metallic foil has the non-planar shape, the deposition surface of the metallic foil has a complex shape comprising a concave-shaped portion between two convex-shaped portions. The preceding subject matter of this paragraph characterizes example 12 of the present disclosure, wherein example 12 also includes the subject matter according to example 9, above.

The material deposited onto the metallic foil forms a plurality of fins of the heat exchange feature of the heat sink. The electrical energy is transmitted from the power source through the one or more deposition anodes of the plurality of deposition anodes, through the electrolyte solution, and to the metallic foil, such that the material forms reinforcement members extending between adjacent ones of the plurality of fins. The preceding subject matter of this paragraph characterizes example 13 of the present disclosure, wherein example 13 also includes the subject matter according to any of examples 1-12, above.

The electrical energy is transmitted from the power source through the one or more deposition anodes of the plurality of deposition anodes, through the electrolyte solution, and to the metallic foil, such that the material deposited onto the metallic foil also forms a flange spaced apart from the heat exchange feature and surrounding the heat exchange feature. The preceding subject matter of this paragraph characterizes example 14 of the present disclosure, wherein example 14 also includes the subject matter according to any of examples 1-13, above.

The material, forming the flange, is deposited as a pattern of reinforcement members. The preceding subject matter of this paragraph characterizes example 15 of the present disclosure, wherein example 15 also includes the subject matter according to any of examples 11-14, above.

The electrical energy is transmitted from the power source through the one or more deposition anodes of the plurality of deposition anodes, through the electrolyte solution, and to the metallic foil, such that the material deposited onto the metallic foil also forms a pattern of reinforcement members between the heat exchange feature and the flange and surrounding the heat exchange feature. The preceding subject matter of this paragraph characterizes example 16 of the present disclosure, wherein example 16 also includes the subject matter according to any of examples 11-15, above.

Further disclosed herein is a heatsink made by an electrochemical deposition process. The heatsink includes a metallic foil and a heat exchange feature coupled to the metallic foil. The heat exchange feature includes material electrochemically deposited onto the metallic foil. The heatsink may further include a flange coupled to the metallic foil, spaced apart from heat exchange feature, and surrounding the heat exchange feature. The flange may be at least partially formed by the material electrochemically deposited onto the metallic foil. The preceding subject matter of this paragraph characterizes example 17 of the present disclosure.

A maximum thickness of the metallic foil is between, and inclusive of, 0.025 millimeters (mm) and 0.5 mm. The preceding subject matter of this paragraph characterizes example 18 of the present disclosure, wherein example 18 also includes the subject matter according to example 17, above.

The metallic foil is made of a pure copper and/or copper alloy. The preceding subject matter of this paragraph characterizes example 19 of the present disclosure, wherein example 19 also includes the subject matter according to example 18, above.

The heat exchange feature includes a plurality of fins. The preceding subject matter of this paragraph characterizes example 20 of the present disclosure, wherein example 20 also includes the subject matter according to any of examples 17-19, above.

The heat exchange feature further includes reinforcement members extending between adjacent ones of the plurality of fins. The preceding subject matter of this paragraph characterizes example 21 of the present disclosure, wherein example 21 also includes the subject matter according to example 20, above.

The material, electrochemically deposited onto the metallic foil, of the flange forms a pattern of reinforcement members. The preceding subject matter of this paragraph characterizes example 22 of the present disclosure, wherein example 22 also includes the subject matter according to any of examples 17-21, above.

The pattern of reinforcement members has a honeycomb, lattice, triply period minimal surface structure, or other rigid construction. The preceding subject matter of this paragraph characterizes example 23 of the present disclosure, wherein example 23 also includes the subject matter according to example 22, above.

The heatsink further includes a reinforcement structure that is coupled to the metallic foil between the heat exchange feature and the flange, surrounds the heat exchange feature, and is formed by the material electrochemically deposited onto the metallic foil. The preceding subject matter of this paragraph characterizes example 24 of the present disclosure, wherein example 24 also includes the subject matter according to any of examples 17-23, above.

The reinforcement structure has a honeycomb construction. The preceding subject matter of this paragraph characterizes example 25 of the present disclosure, wherein example 25 also includes the subject matter according to example 24, above.

A portion of the metallic foil, to which the heat exchange feature is coupled, has a non-planar shape. The preceding subject matter of this paragraph characterizes example 26 of the present disclosure, wherein example 26 also includes the subject matter according to example 25, above.

The heatsink further includes a groove defined at least partially by the metallic foil and extending continuously around the heat exchange feature. The preceding subject matter of this paragraph characterizes example 27 of the present disclosure, wherein example 27 also includes the subject matter according to any of examples 25-26, above.

Also disclosed herein is a method of making a cathode for an electrochemical deposition system. The method includes positioning a metallic foil onto a support surface of a raised platform of a build plate so that the metallic foil is flush against the support surface and retaining the metallic foil against the build plate via a retaining device so that the metallic foil is sealed to the build plate around the support surface and so that the metallic foil is proud of the retaining device. The preceding subject matter of this paragraph characterizes example 28 of the present disclosure.

The retaining device includes a rigid annular ring and at least one gasket coupled to the rigid annular ring. Retaining the metallic foil against the build plate includes positioning the rigid annular ring about the raised platform so that a peripheral portion of the metallic foil is between the rigid annular ring and the raised platform and clamping the peripheral portion of the metallic foil between the at least one gasket of the retaining device and the raised platform. The preceding subject matter of this paragraph characterizes example 29 of the present disclosure, wherein example 29 also includes the subject matter according to example 28, above.

The raised platform includes at least one second gasket. Retaining the metallic foil against the build plate further includes clamping the peripheral portion of the metallic foil between the rigid annular ring and the at least one second gasket. The preceding subject matter of this paragraph characterizes example 30 of the present disclosure, wherein example 30 also includes the subject matter according to example 29, above.

The method further includes fluidically coupling a vacuum port formed in the support surface of the raised platform to a vacuum source. The preceding subject matter of this paragraph characterizes example 31 of the present disclosure, wherein example 31 also includes the subject matter according to any of examples 28-30, above.

The method further includes fluidically coupling a pressure-sensor port formed in the support surface of the raised platform to a pressure sensor. The preceding subject matter of this paragraph characterizes example 32 of the present disclosure, wherein example 32 also includes the subject matter according to example 31, above.

The method further includes electrically connecting the metallic foil to a power source via an electrical-power line electrically coupled with the build plate. The preceding subject matter of this paragraph characterizes example 33 of the present disclosure, wherein example 33 also includes the subject matter according to any of examples 28-32, above.

The retaining device includes tape. Retaining the metallic foil against the build plate includes adhering the tape to the metallic foil and the build plate. The preceding subject matter of this paragraph characterizes example 34 of the present disclosure, wherein example 34 also includes the subject matter according to any of examples 28-33, above.

The build plate includes a base and the raised platform includes double-sided tape adhered to the base. Positioning the metallic foil onto the support surface includes adhering the metallic foil to the double-sided tape. The preceding subject matter of this paragraph characterizes example 35 of the present disclosure, wherein example 35 also includes the subject matter according to any of examples 34, above.

The metallic foil has a non-planar shape when positioned onto the support surface. The method further includes reshaping the metallic foil from a planar shape to the non-planar shape by pressing the metallic foil using a press tool. The preceding subject matter of this paragraph characterizes example 36 of the present disclosure, wherein example 36 also includes the subject matter according to any of examples 28-35, above.

The press tool includes a press portion including a ram and first biasing elements spaced apart about the ram and biasing the ram in a first direction and a receiver portion comprising a cavity, a receiving plate within the cavity, and second biasing elements biasing the receiver portion in the first direction. The method further includes positioning the metallic foil, in the planar shape, between the press portion and the receiver portion, and moving the ram in a second direction, opposite the first direction, into the cavity to press the metallic foil against the receiving plate, move the metallic foil into the cavity, and move the receiving plate in the second direction through the cavity. The metallic foil, in the planar shape, is larger than a cross-sectional area of the cavity such that a peripheral portion of the metallic foil deforms against the cavity, as the metallic foil is moved into the cavity, to reshape the metallic foil from the planar shape to the non-planar shape. The preceding subject matter of this paragraph characterizes example 37 of the present disclosure, wherein example 37 also includes the subject matter according to example 36, above.

Additionally disclosed herein is a cathode for an electrochemical system. The cathode includes a build plate including a raised platform that defines a support surface. The cathode also includes a metallic foil supported on the support surface of the raised platform. The cathode further includes a retaining device engaged with the metallic foil to retain the metallic foil against the build plate and to seal the build plate around the support surface. The metallic foil is proud of the retaining device. The retaining device includes a rigid annular ring and at least one gasket coupled to the rigid annular ring. a peripheral portion of the metallic foil is between the rigid annular ring and the raised platform. The peripheral portion of the metallic foil is between at least one gasket and the raised platform. The raised platform includes at least one second gasket and the peripheral portion of the metallic foil is between the rigid annular ring and the at least one second gasket. The preceding subject matter of this paragraph characterizes example 38 of the present disclosure.

The metallic foil is made of a copper alloy. The preceding subject matter of this paragraph characterizes example 39 of the present disclosure, wherein example 39 also includes the subject matter according to example 38, above.

A maximum thickness of the metallic foil is between, and inclusive of, 0.025 millimeters (mm) and 0.5 mm. The preceding subject matter of this paragraph characterizes example 40 of the present disclosure, wherein example 40 also includes the subject matter according to any of examples 38-39, above.

The raised platform includes a vacuum port formed in the support surface and configured to be fluidically coupled with a vacuum power source. The preceding subject matter of this paragraph characterizes example 41 of the present disclosure, wherein example 41 also includes the subject matter according to any of examples 38-40, above.

The raised platform further includes a pressure-sensor port formed in the support surface and configured to be fluidically coupled with a pressure sensor. The preceding subject matter of this paragraph characterizes example 42 of the present disclosure, wherein example 42 also includes the subject matter according to example 41, above.

The retaining device includes at least one strip of tape adhered to the metallic foil and the build plate. The preceding subject matter of this paragraph characterizes example 43 of the present disclosure, wherein example 43 also includes the subject matter according to any of examples 38-42, above.

The build plate includes a base and the raised platform includes at least one strip of double-sided tape adhered to the base. The metallic foil is adhered to the support surface of the raised platform via the double-sided tape. The preceding subject matter of this paragraph characterizes example 44 of the present disclosure, wherein example 44 also includes the subject matter according to example 43, above.

The metallic foil has a non-planar shape. The preceding subject matter of this paragraph characterizes example 45 of the present disclosure, wherein example 45 also includes the subject matter according to any of examples 38-44, above.

The described features, structures, advantages, and/or characteristics of the subject matter of the present disclosure may be combined in any suitable manner in one or more examples and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example or implementation. In other instances, additional features and advantages may be recognized in certain examples and/or implementations that may not be present in all examples or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings, which are not necessarily drawn to scale, depict only certain examples of the subject matter and are not therefore to be considered to be limiting of its scope, the subject matter will be described and explained with additional specificity and detail through the use of the drawings, in which:

FIG. 1 is a schematic, side elevation view of an electrochemical deposition system for manufacturing a part, according to one or more examples of the present disclosure;

FIG. 2 is a perspective view of a press tool, shown with a press portion of the press tool separated from a receiver portion of the press tool, according to one or more examples of the present disclosure;

FIG. 3 is a perspective view of the receiver portion of the press tool of FIG. 2, shown with a metallic foil on the receiver portion, according to one or more examples of the present disclosure;

FIG. 4 is a perspective cross-sectional view of the press tool of FIG. 2, taken along the plane 4-4 of FIG. 2 and shown with a press portion of the press tool in an unpressed position, according to one or more examples of the present disclosure;

FIG. 5 is a perspective cross-sectional view of the press tool of FIG. 2, taken along the plane 4-4 of FIG. 2 and shown with the press portion of the press tool in a pressed position, according to one or more examples of the present disclosure;

FIG. 6 is a perspective view of a metallic foil, following a pressing operation by the press tool of FIG. 2, according to one or more examples of the present disclosure;

FIG. 7 is a perspective view of a build plate of a cathode, according to one or more examples of the present disclosure;

FIG. 8 is a perspective view of the metallic foil of FIG. 6 on the build plate of FIG. 7, according to one or more examples of the present disclosure;

FIG. 9 is a perspective view of a retaining device of a cathode being positioned into engagement with the metallic foil on the build plate, according to one or more examples of the present disclosure;

FIG. 10 is a perspective view of the retaining device of FIG. 9 engaged with the metallic foil on the build plate to form the cathode, according to one or more examples of the present disclosure;

FIG. 11 is a schematic, cross-sectional, side elevation view of the cathode of FIG. 10, taken along the plane 11-11 of FIG. 10 and shown with material deposited onto the cathode, according to one or more examples of the present disclosure;

FIG. 12 is a schematic, cross-sectional, side elevation view of a cathode, shown with material deposited onto the cathode, according to one or more examples of the present disclosure;

FIG. 13 is a schematic cross-sectional side elevation view of a heatsink, according to one or more examples of the present disclosure;

FIG. 14 is a schematic cross-sectional side elevation view of another heatsink, according to one or more examples of the present disclosure;

FIG. 15 is a schematic cross-sectional side elevation view of yet another heatsink, according to one or more examples of the present disclosure;

FIG. 16 is a perspective view of another heatsink, according to one or more examples of the present disclosure;

FIG. 17 is a schematic cross-sectional side elevation view of the heatsink of FIG. 16, taken along the plane 17-17 of FIG. 16, according to one or more examples of the present disclosure;

FIG. 18 is a perspective view of another heatsink, according to one or more examples of the present disclosure;

FIG. 19 is a schematic cross-sectional side elevation view of the heatsink of FIG. 18, taken along the plane 19-19 of FIG. 18, according to one or more examples of the present disclosure;

FIG. 20 is a schematic cross-sectional side elevation view of a heatsink, according to one or more examples of the present disclosure;

FIG. 21 is a schematic cross-sectional side elevation view of an integrated circuit assembly, according to one or more examples of the present disclosure;

FIG. 22 is a schematic cross-sectional side elevation view of another integrated circuit assembly, according to one or more examples of the present disclosure;

FIG. 23 is a schematic cross-sectional side elevation view of a heat sink being deformed from an initial shape into a final shape, according to one or more examples of the present disclosure;

FIG. 24 is a schematic cross-sectional side elevation view of a heat sink deformed into a final shape from an initial shape, according to one or more examples of the present disclosure;

FIG. 25 is a schematic cross-sectional side elevation view of a heat sink deformed into another final shape from an initial shape, according to one or more examples of the present disclosure;

FIG. 26 is a block diagram of a method of making a cathode, according to one or more examples of the present disclosure; and

FIG. 27 is a block diagram of a method of making a heatsink, according to one or more examples of the present disclosure.

### DETAILED DESCRIPTION

Reference throughout this specification to “one example,” “an example,” or similar language means that a particular feature, structure, or characteristic described in connection with the example is included in at least one example of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the present disclosure, however, absent an express correlation to indicate otherwise, an implementation may be associated with one or more examples.

Electrochemical additive manufacturing utilizes electrochemical reactions to manufacture parts in an additive manufacturing manner. In an electrochemical additive manufacturing process, a metal part is constructed by plating charged metal ions onto a surface of a cathode in an electrolyte solution. This technique relies on placing an electrode (i.e., anode) physically close to the cathode in the presence of a deposition solution (the electrolyte), and energizing the electrode causing charge to flow through the electrode. This creates an electrochemical reduction reaction to occur at the cathode near the electrode and deposition of material on the cathode. Electrochemical additive manufacturing techniques provide distinct advantages over other types of additive manufacturing processes, such as selective laser melting and electron beam melting. Disclosed herein are cathodes, and methods of making the cathode, for an electrochemical additive manufacturing system. Also disclosed herein are heatsinks, and methods of making heatsinks, which integrate a metallic foil of the cathode to reduce the size and the thermal resistance of the heatsinks. Heatsinks may often take the form of coldplates, and the term heatsink may often be used interchangeably with the term coldplate.

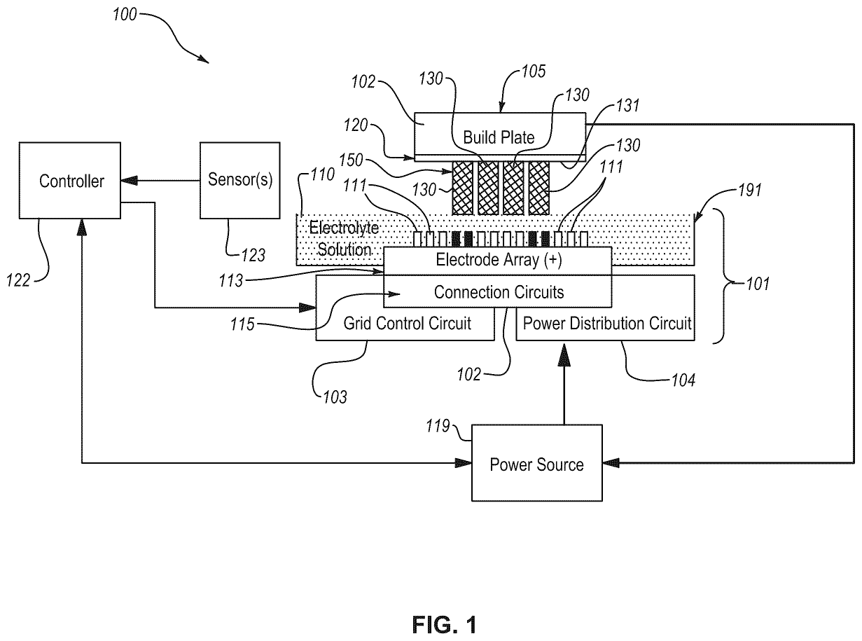

Referring to FIG. 1, according to some examples, an electrochemical deposition system 100 includes a printhead 101 that contains a substrate and at least one electrode 111 coupled with the substrate. In certain examples, the printhead 101 contains a plurality of electrodes 111 arranged into an electrode array 113 on the substrate. The printhead 101 further includes at least one connection circuit 115 corresponding with each one of the electrodes 111 of the printhead 101. The at least one connection circuit 115 is integrated into the substrate of the printhead 101. Accordingly, in examples where the printhead 101 contains an electrode array 113, the printhead 101 includes a plurality of connection circuits 115 integrated into the substrate. The connection circuits 115 can be organized into a matrix arrangement, in some examples, thereby supporting a high resolution of electrodes 111. The electrodes 111 of the electrode array 113 are arranged to form a two-dimensional grid in some examples. In FIG. 1, one dimension of the grid is shown with the other dimension of the grid going into and/or coming out of the page.

The printhead 101 further includes a grid control circuit 103 that transmits control signals to the connection circuits 115 to control the amount of electrical current flowing through each one of the electrodes 111 of the electrode array 113. The printhead 101 additionally includes a power distribution circuit 104. The electrical current, supplied to the electrodes 111 via control of the grid control circuit 103, is provided by the power distribution circuit 104, which routes power from an electrical power source 119 of the electrochemical deposition system 100 to the connection circuits 115 and then to the electrodes 111. Although not shown, in some examples, the printhead 101 also includes features, such as insulation layers, that can help protect the electrodes 111 and other features of the printhead 101 from an electrolyte solution 110, as described in more detail below.

The electrochemical deposition system 100 further includes a cathode 105 and the electrolyte solution 110, which can be contained within a partially enclosed container or electrodeposition cell 191. The cathode 105 includes a build plate 102 and a metallic foil 120 on the build plate 102. In some examples, the electrolyte solution 110 includes one or more of, but not limited to, plating baths, associated with copper, nickel, tin, silver, gold, lead, etc., and which typically include of water, an acid (such as sulfuric acid), metallic salt, and additives (such as levelers, suppressors, surfactants, accelerators, grain refiners, and pH buffers).

The electrochemical deposition system 100 is configured to move the printhead 101 relative to the electrolyte solution 110 such that the electrodes 111 of the electrode array 113 are submersed in the electrolyte solution 110. When submersed in the electrolyte solution 110, as shown in FIG. 1, when the cathode 105 (e.g., the metallic foil 120, and at least one of the electrodes 111 are connected to an electrical power source 119, and when an electrical current is supplied to the electrodes 111 from the electrical power source 119, an electrical path (or current) is formed through the electrolyte solution 110 from each one of the electrodes 111 to the cathode 105. In such an example, the metallic foil 120 functions as the cathode of the cathode-anode circuit of the electrochemical deposition system 100. The electrical paths in the electrolyte solution 110 induce electrochemical reactions in the electrolyte solution 110, between the electrodes 111 and a deposition surface 121 (e.g., conductive surface) of the metallic foil 120, which results in the formation (e.g., deposition) of material 130 (e.g., layers of metal) on the deposition surface 111 of the metallic foil 120 at locations corresponding to the locations of the electrodes 111. The material 130, which can be layers of metal, formed by supplying electrical current to multiple electrodes 111 form one or more layers or portions of a part in some examples.

In some examples, the electrodes 111 of the electrode array 113 are densely packed on the substrate of the printhead 101. The area number density or area concentration of the electrodes 111 is proportional to the resolution of the object capable of being formed from the material 130 deposited onto the build plate 102. Generally, the higher the area number density of the electrodes 111, the higher the resolution, detail, and accuracy of the object that can be made from the material 130.

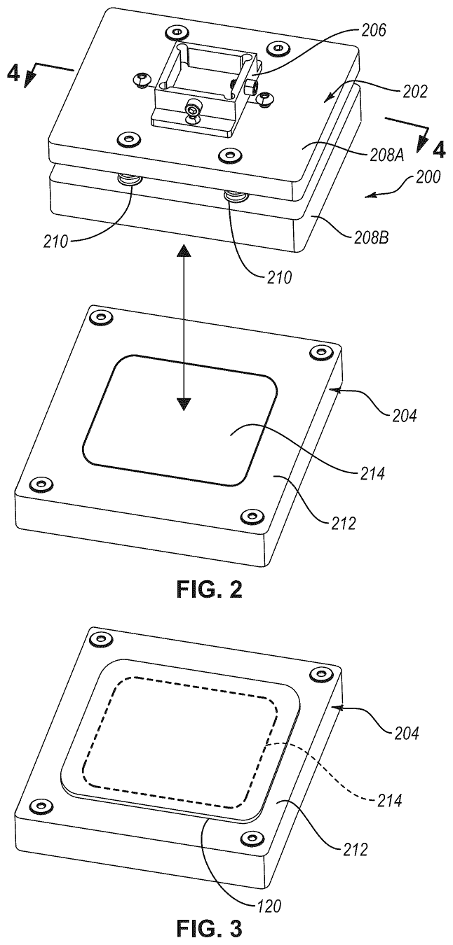

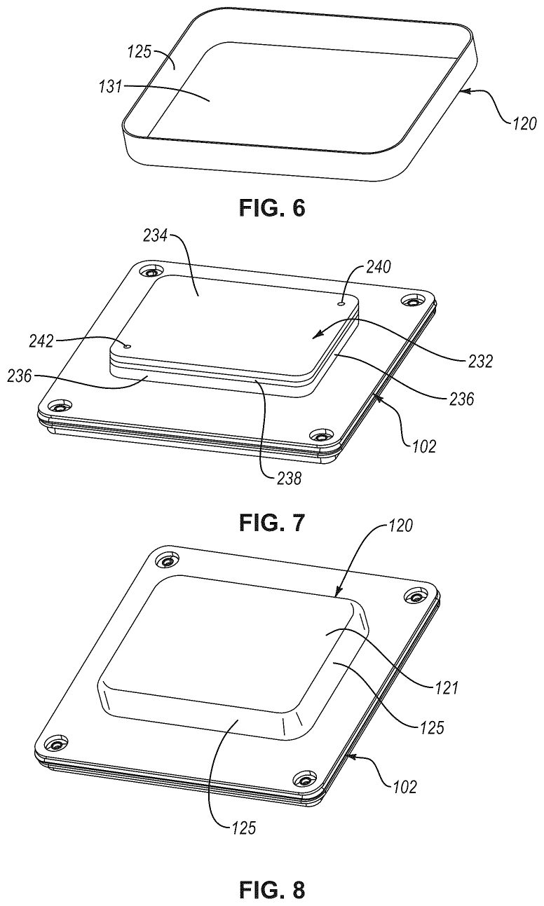

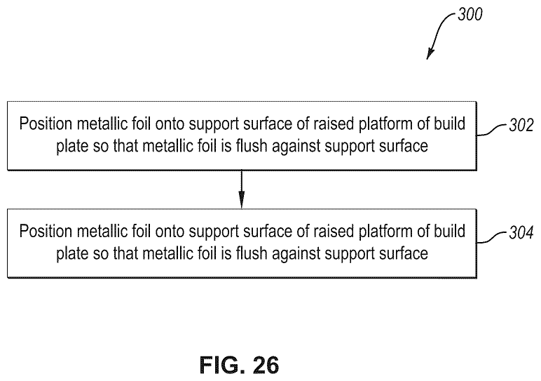

Referring generally to FIG. 26, and particularly to FIGS. 2-10, according to some examples, a method 300 of making a cathode (e.g., the cathode 105) is shown. Referring to FIGS. 7, 9 and 26, the method 300 includes (block 302) positioning a metallic foil 120 onto a support surface 234 of a raised platform 232 of a build plate 102. The metallic foil 120 has a non-planar shape when position onto the support surface 234 (see, e.g., FIG. 6). Accordingly, in some examples, the method 300 includes reshaping the metallic foil 120 from a planar shape (see, e.g., FIG. 3) to the non-planar shape. In certain examples, the metallic foil 120 is reshaped by pressing the metallic foil 120 using a press tool 200 (see, e.g., FIG. 2).

The press tool 200 includes a press portion 202 and a receiver portion 204, which are selectively and removably coupled together. In other words, the press portion 202 and the receiver portion 204 are selectively attachable and selectively separable to enable reshaping of the metallic foil 120. In some examples, the press portion 202 includes receiver-engagement features, such as posts, and the receiver portion 204 includes press-engagement features, such as recesses, which engage each other to temporarily align and couple together the press portion 202 and the receiver portion 204.

The press portion 202 includes an actuator plate 208A and a guide plate 208B. The actuator plate 208A is movably coupled to the guide plate 208B via a plurality of first biasing elements 210 interposed between the actuator plate 208A and the guide plate 208B. The first biasing elements 210 bias the actuator plate 208A away from the guide plate 208B. In some examples, the first biasing elements 210 are compression springs. The press portion 202 further includes a ram 211 fixed to the actuator plate 208A so that the ram 211 is co-movable with the actuator plate 208A. Additionally, the press portion 202 includes an actuator-engagement coupling 206 configured to be coupled to an actuator, such as a hydraulic or pneumatic press. The guide plate 208B includes a guide channel 209 that receives, in slidable engagement, the ram 211 fixed to the actuator plate 208A. As the actuator plate 208A moves relative to the guide plate 208B, the ram 211 moves along the guide channel 209. The ram 211 is fitted within the guide channel 209 via a clearance fit in some examples. The ram 211 has a length that is greater than a length of the guide channel 209 such that as the actuator plate 208A is moved toward the guide plate 208B, the ram 211 can pass entirely through the guide channel 209 (see, e.g., FIG. 5).

The receiver portion 204 includes a cavity 216 and a receiving plate 214 that is in slidable engagement with the cavity 216. Additionally, the receiver portion 204 includes a plurality of second biasing elements 218 within the cavity 216 and engaged with the receiving plate 214 to bias the receiving plate 214 toward the press portion 202. In some examples, the second biasing elements 218 are compression springs. The receiving plate 214 is fitted within the cavity 216 via a clearance fit in some examples.

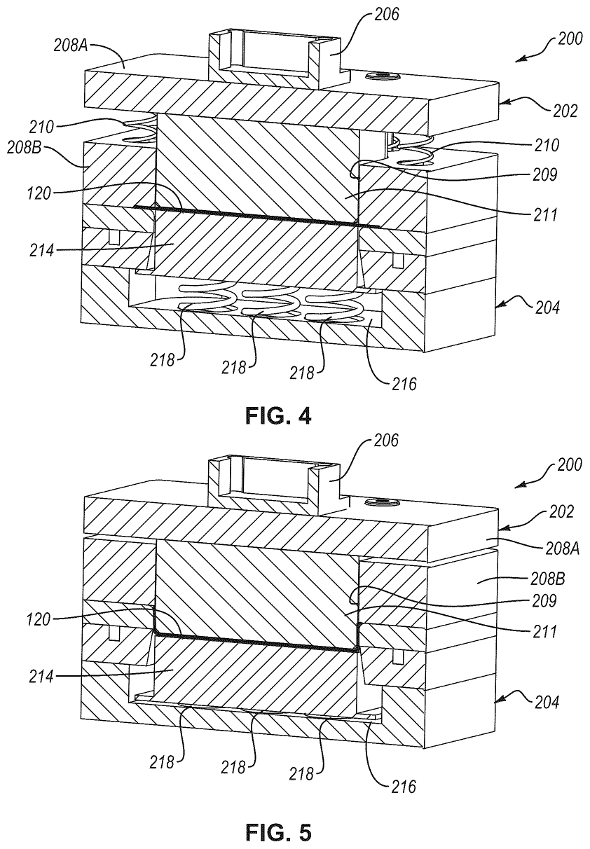

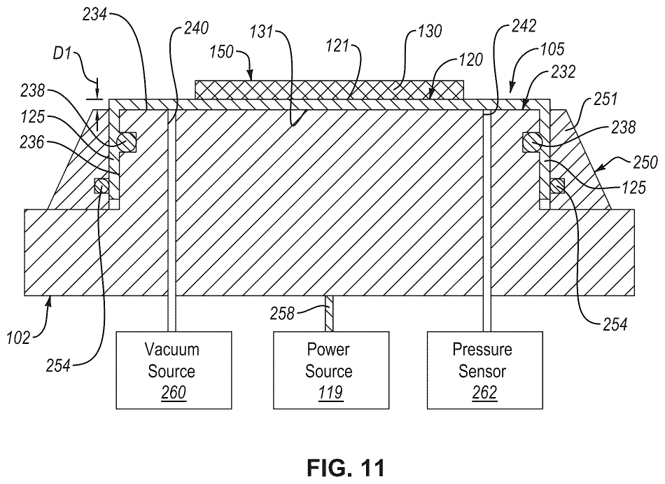

Reshaping the metallic foil 120 using the press tool 200 is accomplished by positioning the metallic foil 120, when in a planar shape, onto the receiving plate 214. As shown in FIG. 3, the metallic foil 120 is larger than (e.g., has a surface area greater than) a cross-section of the receiving plate 214, as well as the ram 211. With the metallic foil 120 positioned on the receiving plate 214, the press portion 202 is attached to the receiver portion 204 so that the metallic foil 120 is sandwiched between the press portion 202 and the receiver portion 204, as shown in FIG. 4. A press, engaged with the actuator-engagement coupling 206 of the press portion 202, is actuated to apply a force to the actuator plate 208A that is greater than and opposite the biasing force of the first biasing elements 210, so that the ram 211 moves along the guide channel 209 toward the receiving plate 214. Eventually, the ram 211 contacts the metallic foil 120 and applies a force to the receiving plate 214 via the metallic foil 120. The force applied to the ram 211 is greater than and opposite the biasing force of the second biasing elements 218 so that further movement of the ram 211 moves the receiving plate 214 along the cavity 216. Because the metallic foil 120 is larger than the receiving plate 214 and the ram 211, a peripheral portion 125 of the metallic foil 120 deforms against the cavity 216 as the metallic foil 120 is forced into the cavity 216 (see, e.g., FIG. 5), leaving a planar portion of the metallic foil 120. The planar portion is defined by an interior planar surface 131 (see, e.g., FIGS. 6 and 11) and a deposition surface 121, which is planar and is opposite the interior planar surface 131. The deformation of the metallic foil 120 in this manner reshapes the metallic foil 120 from the planar shape to the non-planar shape.

In some examples, the first biasing elements 210 and the second biasing elements 216 are evenly spaced about the press tool 200. Referring to FIGS. 6 and 8, the uniform distribution of the biasing elements helps ensure the planarity of the deposition surface 121 of the metallic foil 120 by uniformly distributing the force applied by the actuator to the ram 211 and thus to the metallic foil 120. The deposition surface 121, being planar, promotes a high-quality and consistent deposition of the material 130 onto the metallic foil 120. The peripheral portion 125 of the metallic foil 120, being bent (e.g., at 90-degrees) relative to the deposition surface 121, promotes retention and sealing of the metallic foil 120 to the build plate 102, as will described in more detail below.

Referring to FIGS. 7-11 and 26, the method 300 of making the cathode 105 includes (block 304) retaining the metallic foil 120 against the build plate 102 via a retaining device 250. The retaining device 250 helps seal the metallic foil 120 to the build plate 120 around the support surface 234 and enables the metallic foil 120 to be proud (surface above) of the retaining device 250. The support surface 234 of the raised platform 232 of the build plate 102 is planar, which enables the planar portion of the metallic foil 120 that defines the deposition surface 121 to be flush against the support surface 234. The retaining device 250 helps to ensure that the planar portion of the metallic foil 120 (i.e., the deposition surface 121) remains flush against the support surface 234 during an electrochemical additive manufacturing process.

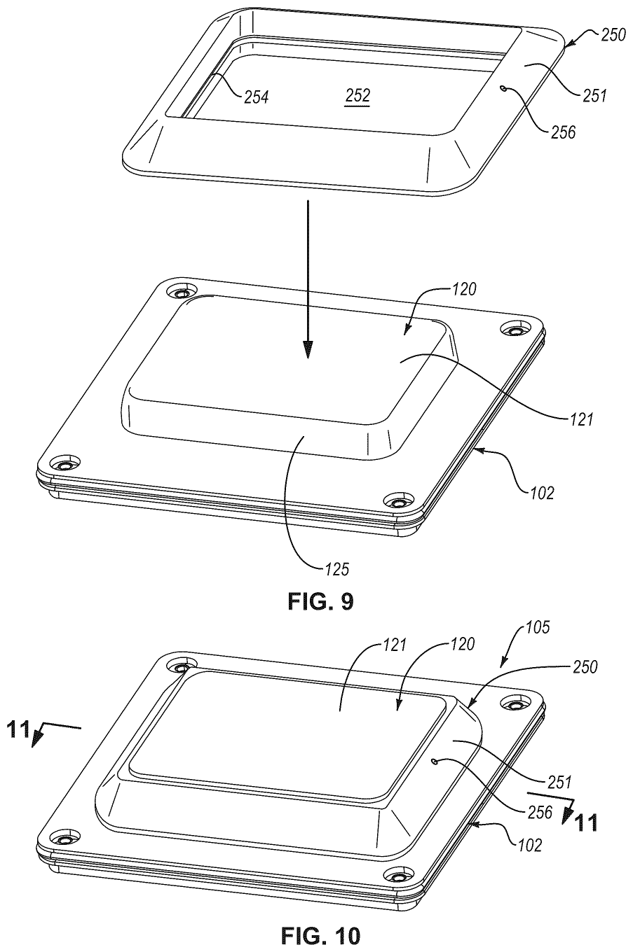

In some examples, the retaining device 250 includes a rigid annular ring 251 and a gasket 254 coupled to the rigid annular ring 251 (see, e.g., FIGS. 9 and 11). The rigid annular ring 251 is more rigid than the gasket 254. According to certain examples, the rigid annular ring 251 is made of an electrically non-conductive material, such as a polymeric material, ceramic material, and/or the like. The rigid annular ring 251 defines a central aperture 252 having a size and shape that corresponds with (e.g., matches) the size and shape of the metallic foil 120, after being reshaped, and the raised platform 232 of the build plate 102. The rigid annular ring 251 also includes an annular channel located adjacent to the central aperture 252. The annular channel is configured to receive and retain the gasket 254. When received within the annular channel, a portion of the gasket 254 is located within the central aperture 252 about the perimeter of the central aperture 252. The gasket 254 can be any of various types of gaskets, such as an O-ring, and be made of any of various types of materials conducive to creating a seal, such as a rubber material. The rigid annular ring 251 has a height that is less than a height of the raised platform 232 by an amount equal to a distance D1 (see, e.g., FIG. 11).

Referring to FIG. 11, the rigid annular ring 251 helps to retain the metallic foil 120 against the build plate 102 by positioning the rigid annular ring 251 about the raised platform 232 so that the peripheral portion 125 of the metallic foil 120 is between the rigid annular ring 251 and a sidewall 236 of the raised platform 232. In this position, the gasket 254 deforms and applies a sealing pressure against the peripheral portion 125 of the metallic foil 120 to effectively clamp the peripheral portion 125 between the gasket 254 and the sidewall 236 of the raised platform 232.

In some examples, the metallic foil 120 is further retained against the build plate 102 via a second gasket 238 of the raised platform 232 of the build plate 102. As shown in FIGS. 7 and 11, the raised platform 232 includes an annular channel formed in the sidewall 236 of the raised platform 232. The annular channel of the raised platform 232 is configured to receive and retain the second gasket 238. When received within the annular channel, the second gasket 238 protrudes from the peripheral extent of the sidewall 236. The second gasket 238 can be the same type or a different type of gasket as the gasket 254. When the rigid annular ring 251 is positioned about the raised platform 232, the second gasket 238 applies a sealing pressure against the peripheral portion 125 of the metallic foil 120 to effectively clamp the peripheral portion 125 between the rigid annular ring 251 and the second gasket 238. The sealing pressures of the gasket 254 and the second gasket 238 are in opposite directions, which helps to ensure the metallic foil 120 is adequately retained on the raised platform 232.

In addition to helping retain the metallic foil 120, the second gasket 238 also helps to create a seal between the metallic foil 120 and the raised platform 232. This seals the space between the support surface 234 of the raised platform 232 and the planar or deposition surface 121 of the metallic foil 120. In some examples, to promote flushness of the deposition surface 121 with the support surface 234, a negative pressure (i.e., vacuum) condition is created within the space between the support surface 234 and the deposition surface 121. The seal created by the second gasket 238 enables the creation of the negative pressure condition. Although only one gasket 254 and only one second gasket 238 are shown, in other examples, the cathode 105 can include more than one gasket 254 and more than one second gasket 238.

Referring to FIGS. 7 and 11, in some examples, the build plate 102 further includes a vacuum port 240 and a pressure-sensor port 242 formed in the raised platform 232 and open to the support surface 234. The cathode 105 further includes a vacuum source 260 fluidically coupled with the vacuum port 240. The vacuum source 260 is selectively operable to pull air and lower the pressure within the space between the support surface 234 and the deposition surface 121, thus creating a negative pressure environment within the space. The cathode 105 further includes a pressure sensor 262 fluidically coupled with the pressure-sensor port 242 and configured to detect the pressure within the space between the support surface 234 and the deposition surface 121. In some examples, the vacuum source 260 lowers the pressure within the space until an optimal pressure is reached, as detected by the pressure sensor 262.

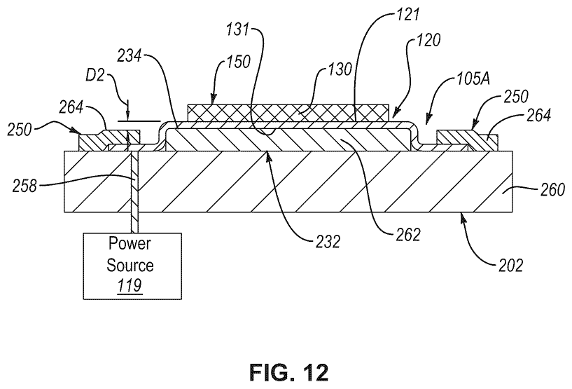

In alternative examples, as shown in FIG. 12, instead of, or in addition to, the rigid annular ring 251, the retaining device 250 of a cathode 105A includes tape 264 (i.e., one or more strips of the tape 264). Accordingly, retaining the metallic foil 120 against the build plate 102 includes adhering the tape 264 to the metallic foil 120 and the build plate 102. According to certain examples, the build plate 102 includes a base 260 and the raised platform 232 is a double-sided tape 262 (i.e., one or more strips of the double-sided tape 262). The double-sided tape 262 is adhered to the base 260 and the metallic foil 120 (i.e., the planar deposition surface 121) is adhered to the double-sided tape 262. Therefore, the double-sided tape 162 can be a double-sided thermal-release tape in some examples.

The build plate 102, the metallic foil 120, and the retaining device 250 form the cathode 105, as well as the cathode 105A. Additionally, each one of the cathode 105 and the cathode 105A includes an electrical-power line 258 that is electrically coupled with the metallic foil 120. The electrical-power line 258 is further electrically coupled with the power source 119 to enable the flow of electrical power, from the power source 119, through the metallic foil 120. As shown in FIG. 11, the electrical-power line 258 is indirectly electrically coupled with the metallic foil 120 via contact with the build plate 102. In other words, the build plate 102 can be made of an electrically conductive material such that the flow of electrical power between the metallic foil 120 and the electrical-power line 258 is facilitated by the build plate 102. Alternatively, such as shown in FIG. 12 and in association with the cathode 105A, the electrical-power line 258 can be directly electrically coupled with the metallic foil 120 by passing through the build plate 102.

When the retaining device 250 is engaged with the metallic foil 120 to retain the metallic foil 120 against the build plate 102 and to seal the build plate 102 around the support surface 234, the metallic foil 120 is proud of the retaining device 250. For example, as shown in FIG. 11, when the retaining device 250 includes the rigid annular ring 251, a first distance D1 or offset is defined between the deposition surface 121 and the top or an uppermost surface of the rigid annular ring 251. Similarly, in the alternative example of FIG. 12, a second distance D2 or offset is defined between the deposition surface 121 and the top or an uppermost surface of the tape 264. The first distance D1 and the second distance D2 helps to ensure the material 130 is cleanly deposited onto the deposition surface 121 and is not inadvertently deposited on or is obstructed by the rigid annular ring 251 and the tape 264, respectively.

The metallic foil 120 is a thin sheet of metallic material. In some examples, a maximum thickness TI of the metallic foil 120 is between, and inclusive of, 0.025 millimeters (mm) and 0.5 mm, such as between, and inclusive of, 0.05 mm and 0.3 mm in one example, and between, and inclusive of, 0.075 mm and 0.1 mm in yet another example. According to various examples, the metallic material of the metallic foil 120 is a copper alloy, silver alloy, and/or the like.

Although in the illustrated examples, the press tool 200 is separate from the build plate 102, such that the metallic foil 120, after being shaped by the press tool 200, is removed from the press tool 200 and separately coupled to the build plate 102, in other examples, the build plate is integrated into the press tool 200 such that the metallic foil 120 need not be removed after being formed. For example, after the metallic foil 120 is shaped and formed about the ram 211, as shown in FIG. 5, the press portion 202 can be disengaged with the receiver portion 204 with the metallic foil 120 still formed on the ram 211. In some examples, the actuator plate 208A, including the ram 211, is also decoupled from the guide plate 208B. The press portion 202 becomes the build plate 102 and the ram 211 becomes the raised platform 232. Other features of the cathode 105, such as a vacuum port 240 and a pressure-sensor port 242, can be formed in the ram 211, and the press portion 202 can be electrically coupled with the power source 119. With the press portion 202 acting as the build plate 102, the cathode 105 can be formed quicker and the electrochemical additive manufacturing process can be executed more efficiently and with fewer parts.

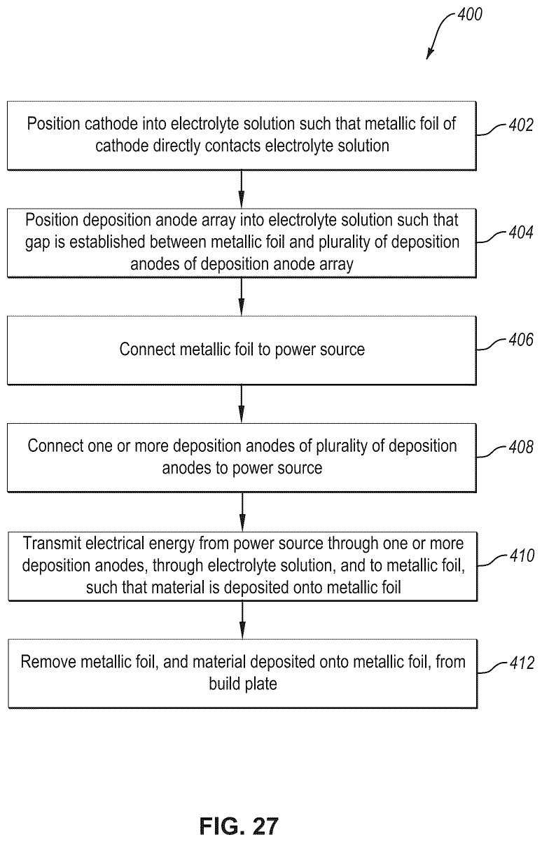

The material 130 is deposited onto the deposition surface 121 of the metallic foil 120 of the cathode (e.g., the cathode 105 or the cathode 105A) using an electrochemical deposition technique, such as one that is similar to the one described above in association with the electrochemical deposition system 100. According to some examples, and with reference to FIG. 27, a method 400 of making a component, such as a heatsink 266, includes (block 402) positioning the cathode 105, which includes the build plate 102 and the metallic foil 120 supported on the build plate 102, into the electrolyte solution 110 such that the metallic foil 120 directly contacts the electrolyte solution 110. The method 400 also includes (block 404) positioning the deposition anode array 113, into the electrolyte solution such that a gap is established between the metallic foil 120 and the plurality of deposition anodes 111. The method 400 additionally includes (block 406) connecting the metallic foil 120 to the power source 119 and (block 408) connecting one or more deposition anodes of the plurality of deposition anodes 111 to the power source 119. The method 400 further includes (block 410) transmitting electrical energy from the power source 119 through the one or more deposition anodes of the plurality of deposition anodes 111, through the electrolyte solution 110, and to the metallic foil 120, such that material 130 is deposited onto the metallic foil 120. The method 400 also includes (block 412) removing the metallic foil 120 and the material 130 deposited onto the metallic foil 120 from the build plate 102. In some examples, after the material 130 is deposited onto the metallic foil 120, and before or after the metallic foil 120 is removed from the build plate 102, the peripheral portion 125 of the metallic foil 120 is removed from the metallic foil 120 such that only the planar portion of the metallic foil 120 remains and forms part of the heat exchanger.

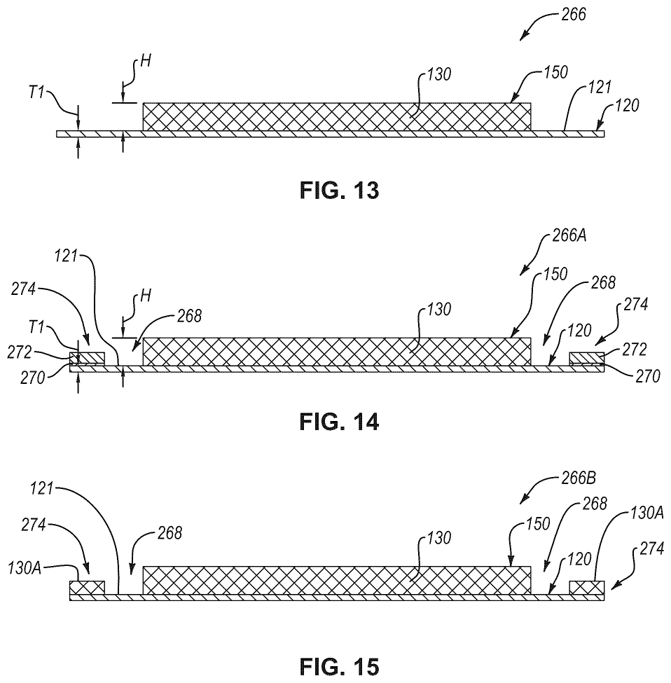

Although other components or parts can be made, in some examples, as shown in FIG. 13, the metallic foil 120 and the material 230 deposited thereon together form a thermal component, such as a heatsink 266 or cold plate. The metallic foil 120 forms a base plate of the heatsink 266 and the material 130 forms at least a portion of a heat exchange feature 150 and/or one or more other features of the heatsink 266. The heat exchange feature 150 includes one or more structures configured to facilitate the transfer (e.g., dissipation or receipt) of heat. In one example, the heat exchange feature 150 includes one or more elongated fins extending uprightly and lengthwise from the metallic foil 120. The elongated fins can be spaced apart from each other across the metallic foil 120, such as shown in FIG. 1. Moreover, the elongated fins can have any of various shapes that promote the transfer of heat, such as shapes that optimize the surface area per unit length of the elongated fins. Whether elongated fins, or other structures, the heat exchange feature 150 has a maximum height H, which is defined as the maximum distance from the deposition surface 121, in a direction perpendicular to the deposition surface 121, to the highest extent of the heat exchange feature 150. In some examples where the heat exchange feature 150 includes elongated fins, the maximum height H is a height of the tallest one or ones of the elongated fins. Although the maximum height H of the heat exchange feature 150 can vary significantly, in some examples, a ratio of the maximum height H of the heat exchange feature 150 to the maximum thickness TI of the metallic foil 120 is between, and inclusive of, 4 and 100, such as between, and inclusive of, 10 and 80 in one example, or between, and inclusive of, 20 and 60 in another example. According to some examples, the heat exchange feature 150 has a maximum height H between, and inclusive of, 1 mm and 5 mm, such as approximately 2 mm in one example.

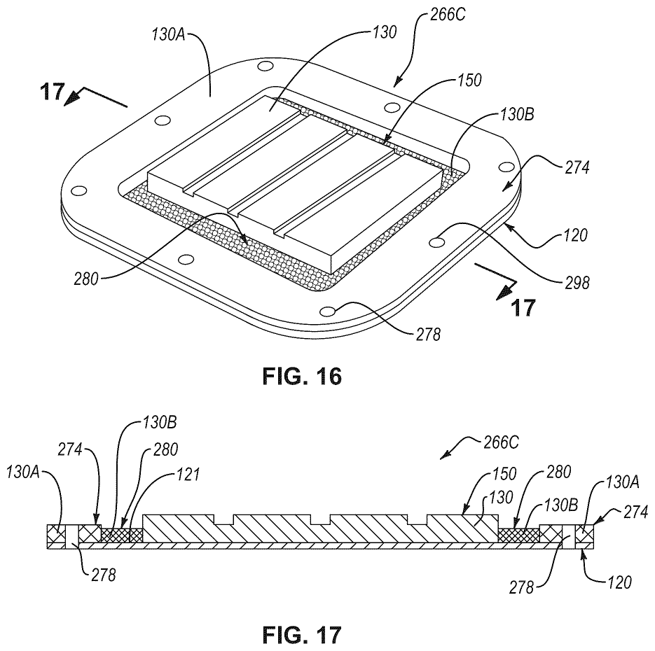

Referring to FIGS. 14-20, according to some examples, the heatsink also includes a flange 274 extending about an outer peripheral portion of the deposition surface 121 of the metallic foil 120 and spaced apart from the heat exchange feature 150. The flange 274 can be a continuous ring-like structure that surrounds or circumscribes the heat exchange feature 150. In other examples, the flange can be a non-continuous structure. Generally, the flange 274 functions as a mount for mounting the heatsink to another one or more parts or structures. In some examples, the flange 274 is used to mount the heatsink to the structure to or from which heat is being transferred. Accordingly, in certain examples, as shown in FIGS. 16 and 17, the flange 274 can include one or more apertures 278 through which corresponding fasteners can extend to secure the heatsink to another structure. The flange 274 has a height relative to the deposition surface 121. In certain examples, the height of the flange 274 is less than the maximum height H of the heat exchange feature 150. According to some examples, a ratio of the maximum height H of the heat exchange feature 150 to the height of the flange 274 is between, and inclusive of, 2 and 50, such as between, and inclusive of, 5 and 40 in one example, or between, and inclusive of, 10 and 30 in another example.

Referring to FIG. 14, in one example, the flange 274 of heatsink 266A is a flange ring 272 that is formed using a process different than that used to deposit the material 130 and is attached to the deposition surface 121 using an adhesive 270 or other attachment technique. At least a portion of the space or gap between the flange 274 and the heat exchange feature 150 can be unfilled or void of any additional features or structures, such as shown in FIGS. 14, 15, and 18-20, so that a groove 268 is defined between the flange 274 and the heat exchange feature 150. The groove 268 is at least partially defined by the deposition surface 121 of the metallic foil 120.

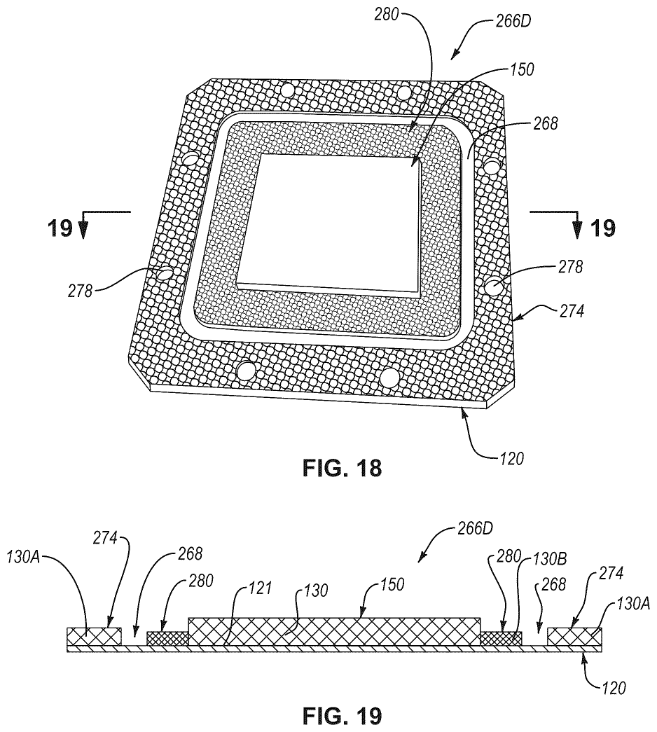

As shown in FIGS. 15-20, in some examples, the flange 274 is formed by depositing material 130A onto the deposition surface 121 via an electrochemical deposition process. According to some examples, the material 130A is deposited during the same deposition process as the material 130 forming the heat exchange feature 150. In certain examples, the material 130A is the same material as the material 130. In the example of FIG. 15, the material 130A forming the flange 274 of the heatsink 266B is deposited as a solid block of material. However, as shown in FIGS. 18 and 19, the material 130A forming the flange 274 of the heatsink 266D is deposited as a pattern of structures (i.e., reinforcement members), such as honeycomb structures (i.e., honeycomb reinforcement members), which can help to reduce weight while still providing a desired level of strength and/or stiffness. In yet other examples, the flange 274 may have solid side surfaces that define a hollow interior that can be infilled with a filler material.

Referring now to FIG. 16-19, according to certain examples, the gap between the flange 274 and the heat exchange feature 150 can be at least partially filled with a reinforcement structure 280. The reinforcement structure 280 can be formed by depositing material 130B onto the deposition surface 121 via an electrochemical deposition process. According to some examples, the material 130B is deposited during the same deposition process as the material 130 forming the heat exchange feature 150 and/or the material 130A forming the flange. In certain examples, the material 130B is the same material as the material 130 and/or the material 130A. The material 130B forming the reinforcement structure 280 of heatsink 266C and heatsink 266D is deposited as a pattern of reinforcement structures, such as honeycomb structures, lattice structures, triply period minimal surface structures, gyroids, or other rigid construction, which can help to reduce weight while still providing a desired level of strength and/or stiffness. The added strength and/or stiffness provided by the reinforcement structure 280 promotes the overall strength and/or stiffness of the heatsink in view of the relatively low strength and/or stiffness of the metallic foil 120 alone. The reinforcement structure 280 can extend across the entire gap between the flange 274 and the heat exchange feature 150, such as with the heatsink 266C, or only a portion of the gap between the flange 274 and the heat exchange feature 150, such as with the heatsink 266D. In addition to honeycomb or gyroid structures, as mentioned above, the reinforcement structure 280 may include other structures, whether patterned or un-patterned, such as gyroid structures, body-centered cubic structures, rectangular structures, isometric grid structures, and/or other similar structures. The structures of the reinforcement structure 280 can also contribute to the fluid flow characteristics of the resulting design, such as, for example, facilitating laminar, turbulent, mixing, flow tripping, and/or other types of fluid flow characteristics. Additionally, due to the metallic composition of the reinforcement structure 280, the structures of the reinforcement structure 280 can also promote the transfer of heat.

As shown, in some examples, the reinforcement structure 280 has a height that is less than the height of the flange 274 and less than the height of the heat exchange feature 150. However, in alternative examples, the reinforcement structure 280 can have the same height as or be taller than the flange 274. It is also recognized that the pattern (e.g., stiffness, etc.) of the flange 274, when patterned with reinforcement members, can be the same pattern as or a different pattern than the pattern of the reinforcement structure 280.

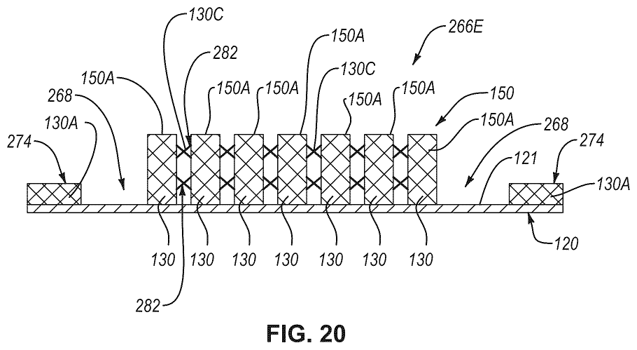

Referring now to FIG. 20, according to certain examples, the heat exchange feature 150 of a heat exchanger 266E includes a plurality of fins 150A spaced apart from each other across the deposition surface 121. The heat exchange feature 150 of the heat exchanger 266E also includes at least one reinforcement member 282 between adjacent ones of the plurality of fins 150A. The reinforcement member 282 extends from one fin to the other of the adjacent ones of the plurality of fins 150A. As shown, in some examples, multiple reinforcement members 282 extend between adjacent ones of the plurality of fins 150A. The reinforcement members 282 can be formed by depositing material 130C onto and between the plurality of fins 150A via an electrochemical deposition process. According to some examples, the material 130C is deposited during the same deposition process as the material 130 forming the heat exchange feature 150 and/or the material 130A forming the flange 274. In certain examples, the material 130C is the same material as the material 130 and/or the material 130A. The material 130C forming the reinforcement members 282 of the heatsink 266E is deposited to form a structure that helps reinforce the plurality of gins 150A relative to each other. Each one of the reinforcement members 282 can be any of various structures, such as cross-beams, diagonal beams, patterned structures (e.g., honeycomb structures), and/or the like.

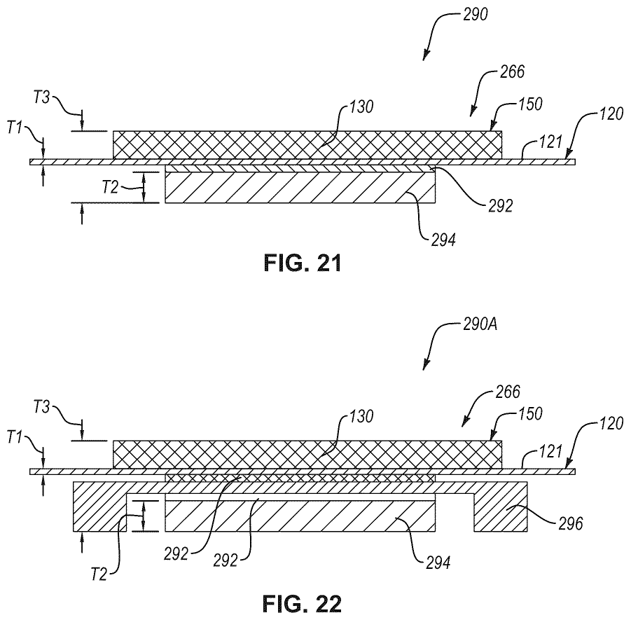

The thinness of the metallic foil 120 of the heatsinks disclosed herein can help to reduce the overall profile and thermal resistance of an electronic assembly 290, as shown in FIG. 21. In some examples, the electronic assembly 290 includes an electronic device 294 that generates heat. The electronic device 294 can be any of various electronic devices, such as microprocessors, integrated circuits (e.g., central processing units, graphic processing units), and/or the like. The electronic device 294 is stacked with a heatsink, such as the heatsink 266, to help transfer heat, generated by the electronic device, away from the electronic device 294. The electronic assembly 290 can include a thermal interface 292 interposed between the electronic device 294 and the metallic foil 120 of the heatsink 266. The thermal interface 292 is in direct contact with the electronic device 294 and the metallic foil 120, and helps transfer heat, via conduction, from the electronic device 194 to the metallic foil 120. Accordingly, the thermal interface 292 is made of a highly conductive material, such as a thermal grease or paste.

Moreover, because of the thinness of the metallic foil 120, the resistance of heat transfer through the metallic foil 120 is much less than with thicker base plates of conventional heatsinks. Therefore, heat from the electronic device 294 is transferred more freely or efficiently to the heat exchange feature 150 of the heat exchanger 266 than with conventional electronic assemblies.

Referring to FIG. 22, in some alternative examples, to help facilitate the transfer of heat from the electronic device 294 to the heat exchanger 266, an electronic assembly 290A includes an integrated heat spreader (IHS) 296. The integrated heat spreader 296 is interposed between the electronic device 294 and the metallic foil 120 of the heat exchanger 266. In some examples, a thermal interface 292, such as that illustrated in FIG. 21, is included between the integrated heat spreader 296 and the metallic foil 120. The integrated heat spreader 296 is configured to spread and more uniformly distribute heat received from the electronic device 294 before transferring the heat to the heat exchanger 266. A second thermal interface 292 can be interposed between the electronic device 294 and the integrated heat spreader 296 to promote heat transfer from the electronic device 294 and the integrated heat spreader 296.

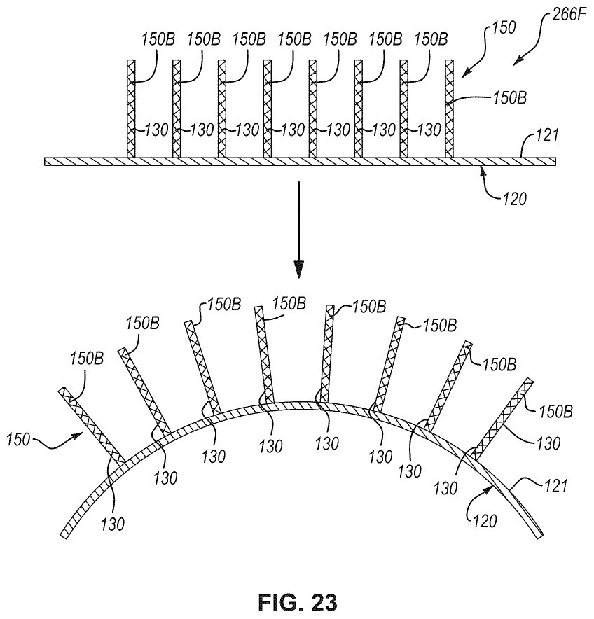

As shown in FIG. 23, according to certain examples and like the heat exchanger 266E, the heat exchanger feature 150 of a heat exchanger 266F includes a plurality of fins 150B spaced apart from each other across the deposition surface 121 of the metallic foil 120. When the material 130 is deposited onto the deposition surface 121 to form the plurality of fins 150B, the deposition surface 121 is planar. However, after the metallic foil 120 and the plurality of fins 150B are removed from the build plate 102, and the peripheral portion 125 is removed, the metallic foil 120 is reshaped (e.g., bent) so that the deposition surface 121 is non-planar or contoured. The thinness of the metallic foil 120 enables the metallic foil 120 to be malleable, deformable, and conducive to reshaping. The reshaping of the metallic foil 120 changes the orientation and spacing of the plurality of fins 150B relative to each other. Additionally, the reshaping of the metallic foil 120 enables the metallic foil 120 to conform to and interface with the shape of a non-planar component, such as a non-planar electronic device. In this manner, the heat exchanger 266F can have any of various shapes and be used to transfer heat from or to components having any of various shapes.

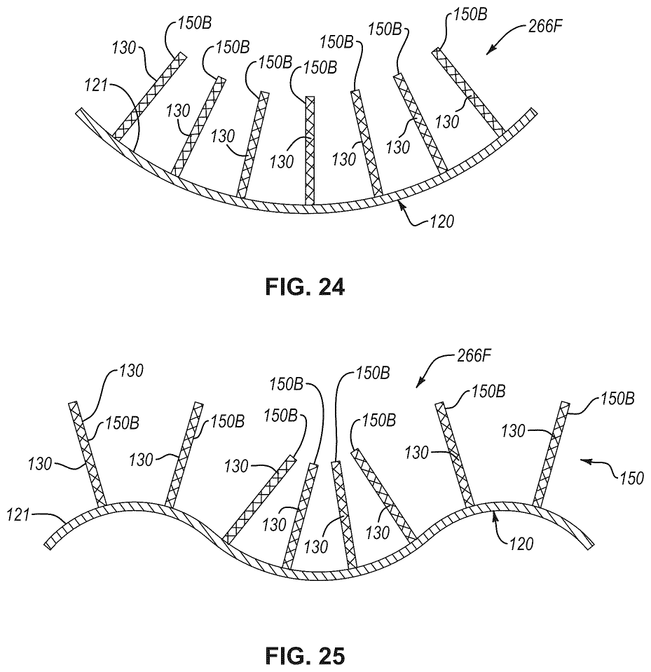

Referring to FIG. 23, in one example, the metallic foil 120 of the heat exchanger 266E is reshaped so that the deposition surface 121 has a single convex shape and the fins 150B are closer together at their respective bases than at their respective tips. Alternatively, referring to FIG. 24, in another example, the metallic foil 120 of the heat exchanger 266E is reshaped so that the deposition surface 121 has a single concave shape and the fins 150B are closer together at their respective tips than at their respective bases. Referring to FIG. 25, in yet another example, the metallic foil 120 of the heat exchanger 266E is reshaped so that the deposition surface 121 has a complex shape, such as multiple curved shapes (e.g., a concave shape between two convex shapes (i.e., a saddle shape)) and multiple inflection points, and so that some of the fins 150B are closer together at their respective tips than at their respective bases and others of the fins are closer together at their respective bases than at their respective tips.

In the above description, certain terms may be used such as “up,” “down,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.” Moreover, unless otherwise noted, as defined herein a plurality of particular features does not necessarily mean every particular feature of an entire set or class of the particular features.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent to another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The term “about” or “substantially” or “approximately” in some embodiments, is defined to mean within +1-5% of a given value, however in additional embodiments any disclosure of “about” or “substantially” or “approximately” may be further narrowed and claimed to mean within +/−4% of a given value, within +/−3% of a given value, within +/−2% of a given value, within +/−1% of a given value, or the exact given value. Further, when at least two values of a variable are disclosed, such disclosure is specifically intended to include the range between the two values regardless of whether they are disclosed with respect to separate embodiments or examples, and specifically intended to include the range of at least the smaller of the two values and/or no more than the larger of the two values. Additionally, when at least three values of a variable are disclosed, such disclosure is specifically intended to include the range between any two of the values regardless of whether they are disclosed with respect to separate embodiments or examples, and specifically intended to include the range of at least the A value and/or no more than the B value, where A may be any of the disclosed values other than the largest disclosed value, and B may be any of the disclosed values other than the smallest disclosed value.

The schematic flow chart diagram included herein is generally set forth as logical flow chart diagram. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not adhere to the order of the corresponding steps shown. Blocks represented by dashed lines indicate alternative operations and/or portions thereof. Dashed lines, if any, connecting the various blocks represent alternative dependencies of the operations or portions thereof. It will be understood that not all dependencies among the various disclosed operations are necessarily represented.

The present subject matter may be embodied in other specific forms without departing from its spirit or essential characteristics. The described examples are to be considered in all respects only as illustrative and not restrictive. All changes which come within the meaning and range of equivalency of the claims are to be embraced within their scope.

What is claimed is:

1. A method of making a heatsink, the method comprising:
positioning a cathode, comprising a build plate and a metallic foil supported on the build plate, into an electrolyte solution such that the metallic foil of the cathode directly contacts the electrolyte solution;
positioning a deposition anode array, comprising a plurality of deposition anodes, into the electrolyte solution such that a gap is established between the metallic foil and the plurality of deposition anodes;
connecting the metallic foil to a power source;
connecting one or more deposition anodes of the plurality of deposition anodes to the power source;
transmitting electrical energy from the power source through the one or more deposition anodes of the plurality of deposition anodes, through the electrolyte solution, and to the metallic foil, such that material is deposited onto the metallic foil and forms at least a portion of a heat exchange feature of the heatsink; and
removing the metallic foil, and the material deposited onto the metallic foil, from the build plate, wherein the heatsink comprises the metallic foil and the material deposited onto the metallic foil.

2. The method according to claim 1, wherein:
the build plate comprises a raised platform;
the cathode further comprises a retaining device engaged with the metallic foil to retain the metallic foil against the build plate and to seal the build plate around a support surface of the raised platform;
a deposition surface of the metallic foil is proud of the retaining device; and
the material is deposited onto the deposition surface of the metallic foil.

3. The method according to claim 1, further comprising urging the metallic foil against the build plate via negative pressure.

4. The method according to claim 3, further comprising sensing a pressure between the metallic foil and the build plate.

5. The method according to claim 4, further comprising adjusting the negative pressure in response to a sensed pressure between the metallic foil and the build plate being outside of a desired negative pressure range.

6. The method according to claim 3, wherein removing the metallic foil, and the material deposited onto the metallic foil, from the build plate comprises removing the negative pressure between the metallic foil and the build plate.

7. The method according to claim 1, further comprising trimming a peripheral portion from the metallic foil after the metallic foil, and the material deposited onto the metallic foil, are removed from the build plate.

8. The method according to claim 1, further comprising reshaping the metallic foil after the metallic foil, and the material deposited onto the metallic foil, are removed from the build plate.

9. The method according to claim 8, wherein reshaping the metallic foil comprises bending the metallic foil from a planar shape to a non-planar shape.

10. The method according to claim 9, wherein:
the material is deposited onto a deposition surface of the metallic foil; and
when the metallic foil has the non-planar shape, the deposition surface of the metallic foil has a convex shape.

11. The method according to claim 9, wherein:
the material is deposited onto a deposition surface of the metallic foil; and
when the metallic foil has the non-planar shape, the deposition surface of the metallic foil has a concave shape.

12. The method according to claim 9, wherein:
the material is deposited onto a deposition surface of the metallic foil; and
when the metallic foil has the non-planar shape, the deposition surface of the metallic foil has a complex shape comprising a concave-shaped portion between two convex-shaped portions.

13. The method according to claim 1, wherein
the material deposited onto the metallic foil forms a plurality of fins of the heat exchange feature of the heat sink; and
the electrical energy is transmitted from the power source through the one or more deposition anodes of the plurality of deposition anodes, through the electrolyte solution, and to the metallic foil, such that the material forms reinforcement members extending between adjacent ones of the plurality of fins.

14. The method according to claim 1, wherein the electrical energy is transmitted from the power source through the one or more deposition anodes of the plurality of deposition anodes, through the electrolyte solution, and to the metallic foil, such that the material deposited onto the metallic foil also forms a flange spaced apart from the heat exchange feature and surrounding the heat exchange feature.

15. The method according to claim 11, wherein the material, forming the flange, is deposited as a pattern of reinforcement members.

16. The method according to claim 11, wherein the electrical energy is transmitted from the power source through the one or more deposition anodes of the plurality of deposition anodes, through the electrolyte solution, and to the metallic foil, such that the material deposited onto the metallic foil also forms a pattern of reinforcement members between the heat exchange feature and the flange and surrounding the heat exchange feature.

17. A heatsink made by an electrochemical deposition process, the heatsink comprising:
a metallic foil;
a heat exchange feature coupled to the metallic foil, wherein the heat exchange feature comprises material electrochemically deposited onto the metallic foil; and
a flange coupled to the metallic foil, spaced apart from heat exchange feature, and surrounding the heat exchange feature, wherein the flange is at least partially formed by the material electrochemically deposited onto the metallic foil.

18. The heatsink according to claim 17, wherein a maximum thickness of the metallic foil is between, and inclusive of, 0.025 millimeters (mm) and 0.5 mm.

19. The heatsink according to claim 18, wherein the metallic foil is made of at least one of pure copper or a copper alloy.

20. The heatsink according to claim 17, wherein the heat exchange feature comprises a plurality of fins.

21. The heatsink according to claim 20, wherein the heat exchange feature further comprises reinforcement members extending between adjacent ones of the plurality of fins.

22. The heatsink according to claim 17, wherein the material, electrochemically deposited onto the metallic foil, of the flange forms a pattern of reinforcement members.

23. The heatsink according to claim 22, wherein the pattern of reinforcement members has at least one of a honeycomb construction, a lattice construction, or a triply period minimal surface structure construction.

24. The heatsink according to claim 17, further comprising a reinforcement structure that:
is coupled to the metallic foil between the heat exchange feature and the flange;
surrounds the heat exchange feature; and
is formed by the material electrochemically deposited onto the metallic foil.

25. The heatsink according to claim 24, wherein the reinforcement structure has a honeycomb construction.

26. The heatsink according to claim 25, wherein a portion of the metallic foil, to which the heat exchange feature is coupled, has a non-planar shape.

27. The heatsink according to claim 25, further comprising a groove defined at least partially by the metallic foil and extending continuously around the heat exchange feature.
